(19) United States
(12) Patent Application Publication
(10) Pub. No.: US 2023/0186461 A1
(43) Pub. Date: Jun. 15, 2023

(54) DYNAMIC MODELING FOR SEMICONDUCTOR SUBSTRATE DEFECT DETECTION

(71) Applicant: Onto Innovation Inc., Wilmington, MA (US)

(72) Inventor: Xin Song, Andover, MA (US)

(21) Appl. No.: 18/062,112

(22) Filed: Dec. 6, 2022

Related U.S. Application Data
(60) Provisional application No. 63/288,742, filed on Dec. 13, 2021.

(51) Int. Cl. G06T 7/00; H01L 21/67

(52) U.S. Cl. CPC G06T 7/001; H01L 21/67288; G06T 2207/30148

(57) ABSTRACT

Dynamic modeling for detecting and classifying defects of fabricated substrates, such as semiconductor substrates. A model includes pixel-by-pixel distributions of pixel data that define a range of known acceptability for substrates based on images of those substrates. The range of acceptability can be defined between upper and lower thresholds. The model is dynamically updated as new imaging data of substrates is obtained, and particularly new imaging data for which an imaging factor not relevant to substrate acceptability has changed. The model can be updated by shifting one or more of the thresholds for one or more of the pixels.

### CROSS-REFERENCE TO RELATED APPLICATIONS

This application claims the benefit of U.S. patent application Ser. No. 63/288,742, filed on Dec. 13, 2021, the disclosure of which is incorporated herein by reference in its entirety. To the extent appropriate, a claim of priority is made to the above disclosed application.

### FIELD OF DISCLOSURE

The present disclosure is directed to acceptability and non-acceptability determinations of substrates.

### BACKGROUND

Semiconductor substrates are manufactured or fabricated as part of the formation of semiconductor chips or other types of integrated circuits (ICs). The components of the ultimate IC may be incorporated into the substrate through a series of fabrication steps. The fabrication steps may include deposition steps where a thin film layer is added onto the substrate. The substrate then may be coated with a photoresist and the circuit pattern of a reticle may be projected onto the substrate using lithography techniques. Etching processes may then occur. At each fabrication step, the tool performing the fabrication step may cause defects or imperfections on the substrate.

In some applications, a semiconductor substrate consists of dies. A die is a block of semiconducting material (e.g., silicon) on which a given functional circuit is fabricated. For example, a functional circuit can take the form of a central processing unit. A functional circuit can be batch manufactured on a single substrate. The substrate is then cut into dies, each containing one copy of the circuit. Each die can be rectangularly shaped. A thin, non-functional spacing can be provided between dies, allowing for cutting (e.g., with a saw) of individual dies from a substrate without damaging the circuits.

Dies can be inspected for defects, such as scratches, voids, corrosion, and bridging. If a defect is detected, a decision is made whether to scrap or to keep the substrate. The decision can be based on the type and severity of the detected defect, the type of die, and other factors.

### SUMMARY

In general terms, the present disclosure is directed to improvements in modeling for defect inspection and classification of substrates. Aspects of the present disclosure can be applied to any manufacturing process involving a fabricated substrate for which defects can be detected and classified based on images of the substrate. An example of such a substrate is a semiconductor substrate. An example of a semiconductor substrate is a semiconductor wafer or panel.

A semiconductor substrate can be incorporated into any number of different electronic devices, such as a light emitting diode (LED). In some examples, the modeling aspects, and defect inspection, detection, and classification aspects of the present disclosure can be applied to products containing semiconductor substrates, such as LEDs. That is, methods of the present disclosure can be employed to determine which LEDs in a group of LEDs are acceptable, and which LEDs are unacceptable and should be scrapped.

Certain embodiments of the present disclosure relate to computer-implemented methods. Certain embodiments of the present disclosure relate to computer systems. Certain embodiments of the present disclosure relate to instructions executable by one or more processors and stored on a non-transitory computer-readable medium.

According to certain specific aspects of the present disclosure, a computer-implemented method for determining acceptability of a substrate, includes: generating a model representing image data obtained from reference images of first substrates, each reference image including pixels that correspond to pixels of each of the other reference images, the model defining, for each pixel, a range of acceptable image values; receiving new image data obtained from a second substrate; and updating the model to generate an updated model, including modifying the range of acceptable image values based on the new image data to generate a modified range.

According to further specific aspects of the present disclosure, computer-implemented method for determining acceptability of a substrate, includes: generating a model representing image data obtained from reference images of a full die of first semiconductor substrates, each reference image including pixels that correspond to pixels of each of the other reference images, the model defining, for each pixel, a range of acceptable image values; receiving new image data obtained from a full die image of a second semiconductor substrate; determining that an imaging factor not relevant to substrate acceptability was different when the full die image of the second semiconductor substrate was obtained and when the reference images were obtained, and based thereon: updating the model to generate an updated model, including modifying the range of acceptable image values based on the new image data to generate a modified range.

According to further specific aspects of the present disclosure, computer-implemented method for determining acceptability of a substrate, includes: generating a model representing image data obtained from reference images of first substrates, each reference image including pixels that correspond to pixels of each of the other reference images, the model defining, for each pixel, a range of acceptable image values; receiving new image data obtained from a second substrate; and, based on the new image data: updating the model to generate an updated model, including modifying the range of acceptable image values; and determining whether the second substrate is acceptable or unacceptable by comparing the new image data to the model.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Additional aspects, features, and/or advantages of examples will be set forth in part in the description which follows and, in part, will be apparent from the description, or may be learned by practice of the disclosure.

### BRIEF DESCRIPTION OF THE DRAWINGS

Non-limiting and non-exhaustive examples are described with reference to the following figures. Throughout the several figures, and wherever possible, like parts and features are indicated with like reference numbers.

FIG. 1 schematically shows an example system for performing dynamically modeled substrate acceptability determinations of semiconductor substrates in accordance with the present disclosure.

FIG. 2 schematically shows a reference image that can be used by the system of FIG. 1 to build a dynamic model for substrate acceptability determinations.

FIG. 3 schematically shows pixel data of one of the pixels of the reference image of FIG. 2.

FIG. 4 schematically shows a completed and/or updated full die model built using, in part, the pixel data of FIG. 3.

FIG. 5 shows composite pixel data for one of the composite pixels of the full die model of FIG. 4.

FIG. 6 schematically shows an example method of dynamically modeled substrate acceptability determination in accordance with the present disclosure.

FIG. 7 schematically shows an example method of updating model pixel data in accordance with the method of FIG. 6.

FIG. 8 shows a further example method of dynamically modeled substrate acceptability determination in accordance with the present disclosure.

### DETAILED DESCRIPTION

Inspection of a semiconductor substrate can be performed by a visual inspection device, such as a camera, e.g., a high resolution CCD camera. The camera captures image data of the substrate being tested. Other types of imaging devices, including non-visual imaging devices, can be used to obtain image data used to build and update a dynamic substrate acceptability model in accordance with present disclosure. Image data of a candidate substrate can then be compared with image data of the initial or updated model. The model defines a range of substrate acceptability as a function of image data. For instance, the model can define a range of acceptable brightness values for each pixel of an image of a die, or portion of a die, of a wafer or panel.

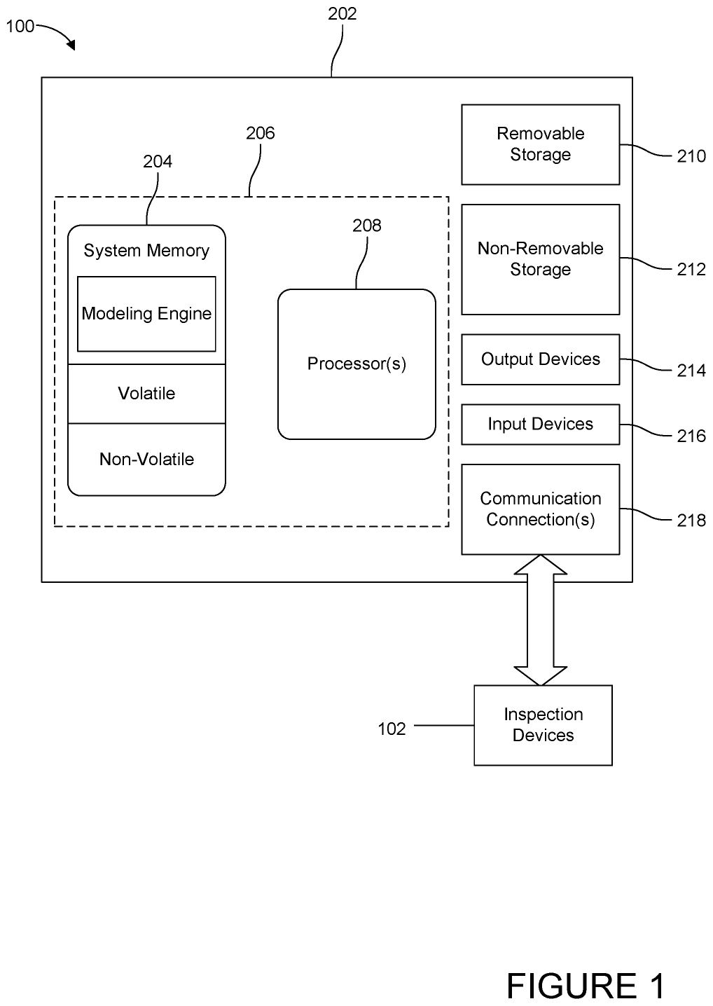

FIG. 1 schematically shows an example system 100 for performing dynamically modeled substrate acceptability determination of semiconductor substrates in accordance with the present disclosure.

The system 100 includes a computing device 202. The computing device 202 may be a server and/or other computing device that performs the operations discussed herein, such as the modeling, model updating, and defect detection, determination and classification operations described herein. The computing device 202 may include computing components 206. The computing components 206 include at least one processor 208 and memory 204. The memory 204 can include a non-transient computer readable medium. Depending on the exact configuration, the memory 204 (storing, among other things, a modeling engine that includes instructions to perform other operations disclosed herein) can be volatile (such as RAM), non-volatile (such as ROM, flash memory, etc.), or some combination of the two. The computing device 202 may include one or more graphics processing units (GPUs) configured to expedite model building and updated and/or application of a model for defect detection and determination. Further, the computing device 202 may also include storage devices (removable 210, and/or non-removable 212) including, but not limited to, solid-state devices, magnetic or optical disks, or tape. Further, the computing device 202 may also have input device(s) 216 such as touch screens, keyboard, mouse, pen, voice input, etc., and/or output device(s) 214 such as a display, speakers, printer, etc. One or more communication connections 218, such as local-area network (LAN), wide-area network (WAN), point-to-point, Bluetooth, RF, etc., may also be incorporated into the computing device 202.

The system 100 can include inspection devices 102 that is/are in operative communication with, e.g., linked via a network and the communications connection(s) 218 to, the computing device 202. The inspection devices 102 can include imaging devices, such as CCD cameras, that take images of semiconductor substrates. The computing device 202 receives those images and, using instructions of the modeling engine, performs the dynamic modelling, defect detection, acceptability determination, and classification operations described herein.

The inspection devices 102 themselves, and/or external attributes of the inspection devices 102, can change over time. For example, a new inspection device 102 may be calibrated differently from a previous inspection device. More generally, for a given die type, die image data, and/or how the image data is obtained can evolve over time or otherwise vary due to external attributes, e.g., factors independent of the actual acceptability or unacceptability of the die. For example, imaging equipment used to obtain the imaging data can be repaired, replaced, or upgraded. As another example, environmental factors present when the image data is, taken (e.g., background noise, lighting) can vary. As other examples, calibration of the fabrication equipment used to fabricate the reference dies can vary, the materials used to fabricate the die can vary in color or reflectiveness, and so forth. Thus, external attributes can also be thought of as a natural variation in pixel image data values due to variables, such as variables associated with one or more of the example factors above, that do not impact the acceptability of a die but do impact the image data obtained from a die when inspecting it for defects that determine its acceptability.

Using the modeling engine, the dynamic modeling performed by the computing device 202 accounts for these variabilities in image data caused by external attributes that are not indicative of substrate defects.

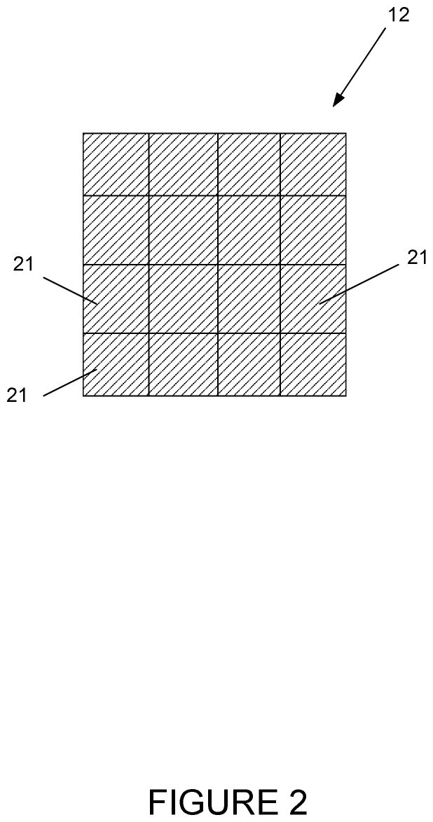

FIG. 2 schematically shows a reference image 12 that can be used by the system of FIG. 1 to build a dynamic model for substrate acceptability determinations. The reference image 12 can be captured using the inspection device(s) 102 (FIG. 1). In some examples, the reference image 12 is a full die reference image, meaning that it includes pixel data for an entire die of a semiconductor wafer or panel. In other examples, the reference image 12 is a partial die reference image, meaning that it includes pixel data from a portion of a die of a semiconductor wafer or panel. Multiple partial die reference images of different portions of the same die can be stitched together to form a full die reference image.

The reference image 12 includes pixels 21, with each pixel represented as a square in an array of squares in FIG. 2 on the reference image 12.

The reference image 12 is known to represent a non-defective die or portion of a die. That is, the die or die portion whose image is taken to generate the reference image 12 is known to be acceptable or, to the extent it has any defects, such defect(s) is/are acceptable.

In some examples, some of reference images 12 used to generate a full die model are known to correspond to unacceptable dies or die portions.

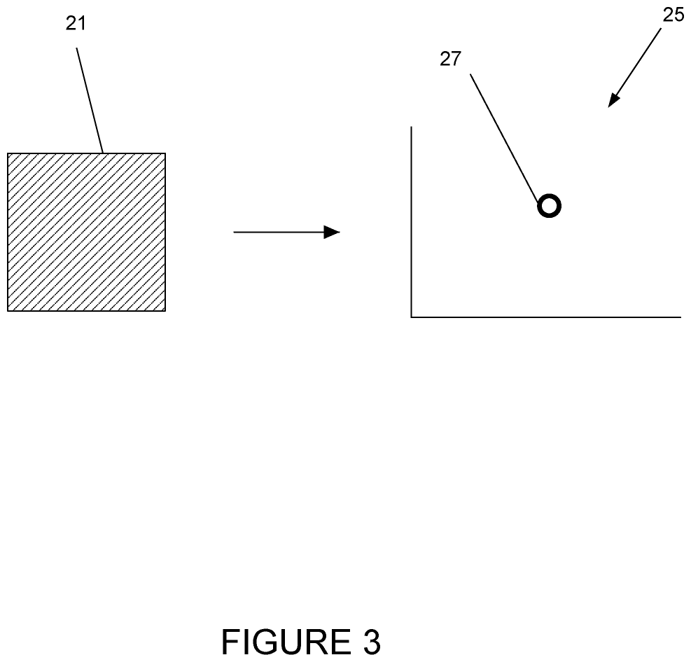

FIG. 3 schematically shows pixel data 25 of one of the pixels 21 of the reference image 12 of FIG. 2. The pixel data 25 can be any visual or other type of data generated on a pixel by pixel basis. One example of pixel data 25 can be brightness. The pixel data 25 includes a single data point 27 corresponding to the pixel data obtained from a pixel 21. For instance, the data point 27 can be a brightness value for a single pixel 21. The modeling engine of the computing device 202 of FIG. 1 can be configured to derive the pixel data from each pixel 21 and to receive input that the derived pixel data corresponds to an acceptable die or die portion.

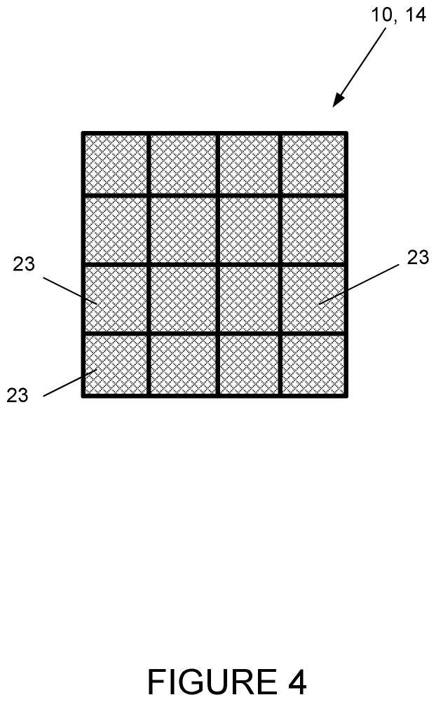

FIG. 4 schematically shows a completed full die model, which can be an initial full die model 10, or an updated full die model 14. An updated full die model 14 has been updated from an initial full die model one or more times based on additional image data taken with imaging equipment under different external characteristics than those used to build the initial full die model. Updating a full die model can be a repetitive, iterative process, with updates to the initial model to a previously updated model continuing to occur as relevant update imaging data is generated by the inspection devices 102 (FIG. 1) during subsequent substrate fabrication runs and fed to the computing device 202.

The full die model 10, 14 is made up of composite pixels 23, with each composite pixel 23 represented as a square in an array of squares in FIG. 4. Each composite pixel 23 is a composite of the relevant pixel data (e.g., brightness) obtained from the corresponding pixel of all the reference images 12 containing that corresponding pixel that were used to generate the full die model 10, 14.

Each composite pixel 23 represents a distribution of pixel data from the reference images that were used to generate that composite pixel. In some examples, the distribution of pixel data represents only pixel data indicative of an acceptable die or die portion. In other examples, in which some of the reference images used to generate the full die model 10, 14 include known unacceptable dies, the distribution represents some pixel data that is indicative of an acceptable die or die portion, and other pixel data that is indicative of an unacceptable die or die portion.

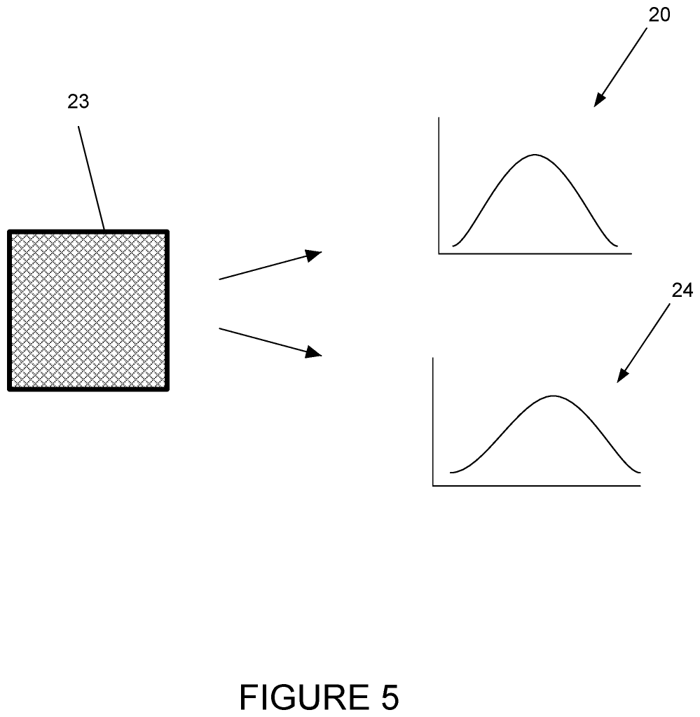

FIG. 5 shows composite pixel data 20, 24 for one of the composite pixels 23 of the full die model of FIG. 4. The composite pixel data 20 is based on the composite pixel 23 of an initial full die model 10 (FIG. 4). The composite pixel data 24 is based on the composite pixel 23 of an updated full die model 14 (FIG. 4).

Each set of composite pixel data 20, 24 is a distribution of pixel data from the corresponding pixel of the underlying references images. The composite pixel data 20 is a distribution of pixel data from the initial set of reference images. The composite pixel data 24 is a distribution of pixel data from the initial set of reference images plus one or more updated reference images generated with updated external attributes.

The modeling engine of the computing device 202 of FIG. 1 can be configured to combine the pixel data from each pixel 21 of each reference image to generate the pixel data distributions of the corresponding composite pixel.

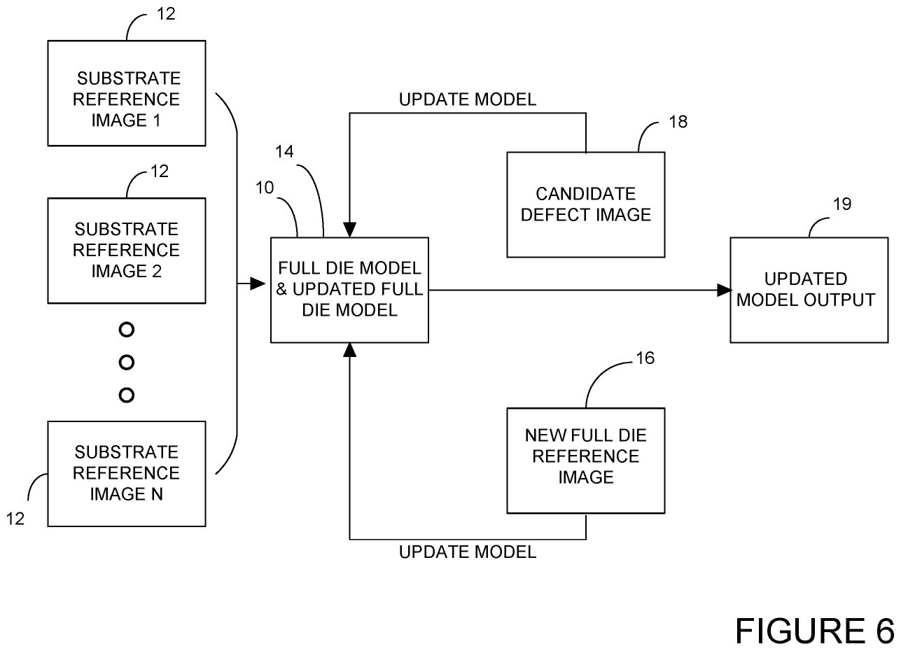

FIG. 6 schematically shows an example method of dynamically modeled substrate acceptability determination in accordance with the present disclosure.

Referring to FIG. 6, the initial full die model 10 can be constructed from multiple substrate reference images 12, with pixel-by-pixel image data from the multiple images being combined to generate the model 10. It can be appreciated that model construction, modification, and application on a pixel-by-pixel basis is just one example implementation of the system 100 (FIG. 1). In other examples other these aspects of the technology can be performed based on different image unit, such as a group of pixels, a portion of a pixel, a spatially defined area of an image defined without pixel identification, and so forth.

In some examples, the substrate reference images 12 are full die reference images and the model 10 is a model of a full die. A full die reference image is an image that includes image data for the entirety of a die corresponding to a given semiconductor component, such as a particular type of functional circuit.

In some examples, each full die reference image 12 is a composite of multiple other images stitched together. For example, each other image can be an image of a different portion of the die. The other images are stitched together to form a full die reference image.

For all of the dies of the full die reference images 12, the acceptability or unacceptability of the corresponding dies is known. At least some of the dies of the full die reference images 12 are known to be acceptable. That is, those dies are either defect free, or have one or more defects that are not significant enough to render the die unacceptable. In some examples, one or more of the dies of the full die reference images 12 are known to be unacceptable.

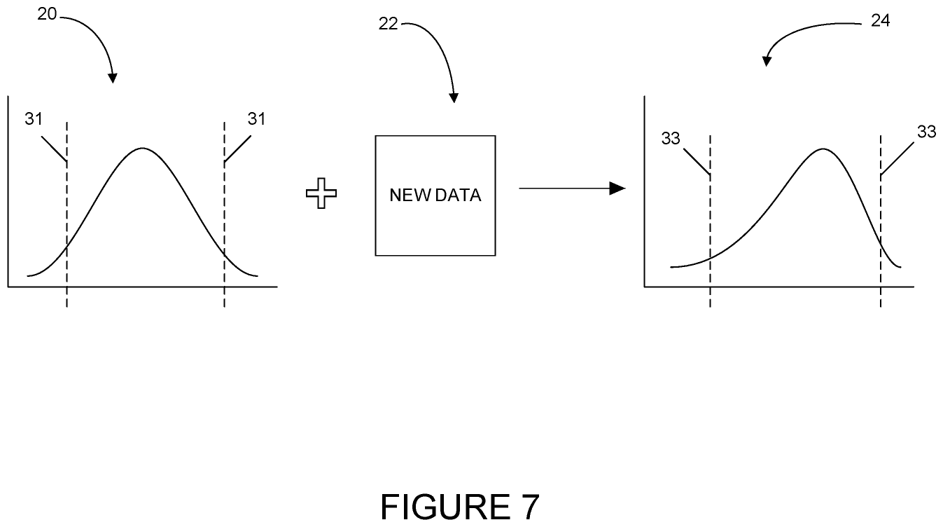

Because multiple full die reference images 12 are used to generate the initial model 10, and because the full die reference images 12 contain differing image data from one image to another, the initial model 10 includes a distribution, of image data for each pixel of the combined image that corresponds to a combination of the reference images 12. The number of full die reference images 12 can be 10's, 100's, 1,000's, 10,000's, or higher. Thus, for each pixel, the initial model 10 can represent a histogram 20 (FIGS. 5, 7) of image data values. The histogram 20 for each pixel defines a population N of reference images (N being a positive integer) used to generate the histogram 20, a mean μ of image data values for the population N, and a standard deviation σ of image data values for the population N.

A reliability of the initial model 10 can be defined as a function of its under inclusiveness and/or over inclusiveness. The initial model 10 is overinclusive to the extent it fails to identify an unacceptable (or killer) defect in a candidate die that is being inspected and compared to the initial model 10. The initial model 10 is underinclusive to the extent it identifies an acceptable die that is being inspected and compared to the initial model 10 as unacceptable due to a killer defect that is not actually present.

Aspects of the present disclosure can improve the reliability of the initial model 10 by dynamically updating the model 10 to generate the updated model(s) 14.

To reduce the impact of variability of external attributes on the model, the initial model 10 is updated with new data. The new data can be image data of known acceptability (e.g., the corresponding dies are known to be acceptable or known to be unacceptable) while having one or more external attributes that differentiate the new data from the initial model 10. As a result, by updating the initial model 10 with the new data, the updated model 14 becomes more reliable than the initial model.

In particular, the new data can be used to dynamically modify the population, the mean and/or standard deviation and threshold(s) of the initial model, thereby modifying the acceptability range to a range that is more reliable at detecting defects based on the updated inspection tools or processes. For instance, for each pixel, the range of acceptability can be defined between upper and lower acceptability thresholds, which themselves can correlate with the standard deviation, or some other statistical measurement.

The new data used to update the model 10 to an updated model 14, can by supplied from any of multiple sources. One example source of the new data is a new full die reference image 16 that is known to represent an acceptable die but having one or more external attributes not yet accounted for in the initial model 10.

Another example source of the new data is a candidate defect image 18. The candidate defect image 18 can be an image of a portion of a die that is being inspected for acceptability using the existing model (i.e., using either the initial model 10 or the updated model 14). The pixels of the image 18 are compared to the corresponding pixels of the full die model, such that the portion of the die captured in the image 18 is aligned with and mapped against the corresponding portion of the full die model. In addition, the candidate defect image 18 can itself be used to update the model to an updated model 14. In some examples, the candidate defect image 18 is used to update the model only if it is determined (e.g., using the model 10, 14) that the portion of the die represented in the image 18 is acceptable. In other examples, the candidate defect image 18 is used to update the model regardless of whether the portion of the die represented in the image is determined to be acceptable.

The model can thus be updated every time it receives a new full die reference image 16 or a new candidate defect image 18. This can occur on a regular basis, e.g., at least once an hour, at least once a minute, or at least once a second, or more frequently or less frequently, providing for highly dynamic thresholding of the model 10, 14. The most current version of the model can then be used to perform defect detection and defect assessment to provide an updated model output 19 for the next candidate die. That is, image data taken from a candidate die is compared to the corresponding distribution of image data of the most current iteration of the full die model 10, 14, and based on the placement of the candidate die data relative to the distribution, is determined by the computing device 202 (FIG. 1) to be an acceptable die (if the candidate die image falls within the acceptable range of the data distribution) or to be an unacceptable die (if the candidate die image falls outside the acceptable range of the data distribution).

FIG. 7 schematically shows an example method of updating model pixel data in accordance with the method of FIG. 6.

The model updating is shown with respect to image data for a single pixel of the model, corresponding to a specific location of a die. New data 22 is used to modify the composite pixel data distribution 20 (or initial pixel-specific image histogram) corresponding to one of the pixels of the initial model, to generate an updated composite pixel image data histogram 24 for that data. The updated pixel image data 24 can have different statistical attributes due to the added data, such as a different population, a different mean, and/or a different standard deviation.

The shape of the distribution changes (e.g., skews) from the composite pixel data 20 to the composite pixel data 24. This change in shape is caused by the introduction of the pixel data from the updated images. Some or all of the updated reference images correspond to acceptable dies or die portions. In some examples, some of the updated reference images can correspond to unacceptable dies or die portions.

The composite pixel data distributions 20, 24 can be any visual or other type of data distributions. One example of distributed pixel data 20, 24 can be brightness. The pixel data is a distribution of individual data points derived from initial reference images in the case of the distribution 20, and initial plus updated reference images in the case of the distribution 24.

In some examples, each distribution corresponds only to acceptable dies. In other examples, each distribution includes a distribution subset corresponding to acceptable dies and one or more distribution subsets corresponding to unacceptable dies. For instance, acceptable dies or die portions can correspond to pixel data in the distribution that falls between upper and lower thresholds 31 for the initial distribution 20, or that falls between upper and lower thresholds 33 for the updated distribution 24.

As mentioned, the new data 22 can cause the data distribution to skew, and/or one or more of the thresholds to move, such that a substrate that would have fallen outside the range between the thresholds 31 for the initial distribution and, therefore, would have been determined unacceptable according to the initial model, falls within the range between the thresholds 33 for the updated distribution and, therefore, is determined acceptable according to the updated model. Conversely, the new data 22 can cause one or more of the thresholds to move, such that a substrate that would have fallen within the range between the thresholds 31 for the initial distribution and, therefore, would have been determined acceptable according to the initial model, can fall outside the range between the thresholds 33 for the updated distribution and, therefore, be determined unacceptable according to the updated model.

The data values corresponding to the thresholds 31, 33 can be selected to optimize the overall system (e.g., to maximize reliability of the substrate acceptability determination while minimizing processing time and resources). For instance, the range between thresholds can be selected to correspond to one (or two or more) standard deviation of the peak of the distribution, with unacceptable dies or die portions corresponding to pixels falling outside of that acceptable range of the distribution.

The computing device 202 (FIG. 1) detects and classifies defects in a candidate substrate or determines that the candidate substrate is acceptable by comparing image data of the candidate substrate to the thresholds of the distribution of image data of the corresponding pixels of the current iteration of the model. In some examples, defect determination and classification (or non-determination) can be performed based on a pixel-by-pixel comparison between the candidate defect image and the current iteration of the full die model.

The initial modeling and model updating of the present disclosure can be computationally highly efficient due to the dynamic updating of the model, e.g., a continuous or nearly continuous model updating operation. Thus, for example, the model does not have to be retrained each time new inspection equipment is used or there is some other change in external attributes. For instance, a change in light intensity at a die inspection due to an inspection tool upgrade or recalibration does not require retraining of the model.

In addition, in some examples, limited data (or data types) is tracked to perform dynamic modification of the model and defect detection and non-detection as described herein, which can further increase computational efficiency. Such data can be limited to, for example, the mean, the standard deviation, and the population, without the computations needed to also process other data from one or more images of the candidate substrate.

In addition, because the model is dynamically updated to account for variability in external attributes, tests of those external attributes (e.g., background lighting tests, noise tests, high contrast tests, low contrast tests, etc.) can be reduced or eliminated, simplifying the overall process of detecting and classifying defects and determining acceptability of substrates.

Additional advantages of embodiments of the present disclosure include shorter substrate inspection times. Shorter inspection times can be due to, e.g., the simplified detection process having fewer steps and tests.

Additional advantages of embodiments of the present disclosure include greater reliability of killer defect determination in substrates due to improved accounting for inspection variability that does not actually impact substrate acceptability. This can reduce unnecessary maintenance and/or replacement of substrate fabrication tools and inspection tools, reduce unnecessary scrapping of acceptable substrates, and increase output of acceptable substrates.

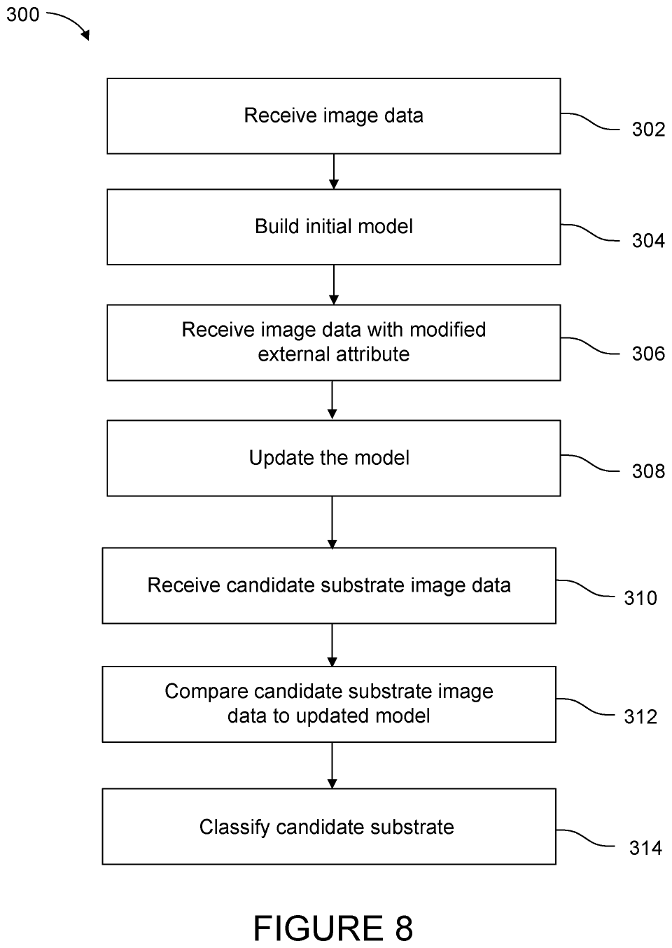

FIG. 8 shows a further example method 300 of dynamically modeled substrate acceptability determination in accordance with the present disclosure.

In certain embodiments, not all of the steps of method 300 are required. In certain embodiments, one or more of the steps of the method 300 can be performed in a different order than the order shown. The steps of the method 300 can be performed by the computing device 202 of the system 100 (FIG. 1).

At a step 302 of the method 300, image data is received by the computing device 202. Such image data can include full die reference images and/or partial die reference images. In some examples, the partial die reference images can be stitched together to generate full die reference images. Each reference image can be tagged to indicate that the corresponding die or die portion is either acceptable or unacceptable. The reference images can be taken of bare substrates, or of substrates present in devices in which they have already been incorporated, such as LEDs.

At a step 304 of the method 300, the initial defect detection model is built by adding together pixel-by-pixel image data from the full die reference images. The generated model is a full die model of composite distributed pixel data for each pixel of the die, the die having known acceptability or unacceptability.

At a step 306 of the method 300, the new image data is received by the computing device 202. The new image data can be derived from a candidate defect image or from a new full die reference image. The new image data can be tagged to indicate that the corresponding die or die portion is either acceptable or unacceptable. The new image data has one or more external attributes that differ from corresponding external attributes of the image data received at the step 302. The new image data can be taken of a bare substrate, or of a substrate present in a device in which the substrate has already been incorporated, such as a LED.

At a step 308 of the method 300, the model is updated using the received new image data. The updated model can have an adjusted distribution of image data for one or more pixels of the die, indicating an adjusted range or thresholding of acceptability or unacceptability of substrates (or devices incorporating the substrates, such as LEDs) as a result of the data distribution skewing caused by the new image data.

The steps 306 and 308 can be repeated one or more times in an ongoing iterative process of updating the model and keeping it up to date with changes to external attributes of substrate inspection devices and processes.

At a step 310 of the method 300, a candidate substrate is inspected and imaged with imaging equipment. The candidate substrate is a substrate for which it is desired to be determined whether the substrate is acceptable, or whether the substrate is unacceptable and should be scrapped. The candidate substrate can be a bare substrate, or a substrate present in a device in which the substrate has already been incorporated, such as a LED.

At a step 312 of the method 300, the candidate substrate image data is compared, e.g., on a pixel by corresponding pixel basis, to the full die model of composite pixel data, to determine where the candidate substrate image data falls on the distribution of image data for each composite pixel of the full-die model. It is determined that the candidate substrate image data, for each pixel, either falls within the acceptable range defined by the distribution of the corresponding composite pixel of the full-die model (and is therefore acceptable), or falls outside that range (and is therefore unacceptable).

At a step 314 of the method 300, the candidate substrate (and, in some cases, the device (e.g., LED) in which the candidate substrate is incorporated) is classified based on the pixel-by-pixel results of the comparison at the step 312. For example, based on the number and placement of pixels determined to be unacceptable at the step 312, the overall candidate substrate or device, or at least that die of the candidate substrate, is classified as either acceptable or unacceptable. In some examples, the additional classifications can be generated for a given detected defect based on the comparison at the step 312. For instance, certain types of defects may be known to have certain signatures or fingerprints in their image data. The computing device 202 (FIG. 1) can have access to a library of such signatures and fingerprints and, by comparing the pixel data of a candidate substrate detected to have a defect to the library, the type of defect can be determined by the computing device 202, as well as the tool that generated the defect, the fabrication processing step at which the defect occurred, and so forth. All of this information about the detected defect, including whether it rendered the die acceptable or unacceptable, can be provided to a user of the computing device 202 via a user interface.

If the candidate substrate (or device incorporating the candidate substrate) is determined to be unacceptable, an alert to that effect can be generated (e.g., via a user interface), and the candidate substrate or device can be scrapped and any indicated maintenance or tool replacement can be performed.

If the candidate substrate (or device incorporating the candidate substrate) is determined to be acceptable, the substrate can proceed to the next step of production or distribution.

In some embodiments, the image data from the candidate substrate image is used to update the model further, particularly if the inspection equipment or process for the candidate substrate included one or more different external attributes.

Although specific embodiments are described herein, the scope of the technology is not limited to those specific embodiments. Moreover, while different examples and embodiments may be described separately, such embodiments and examples may be combined with one another in implementing the technology described herein. One skilled in the art will recognize other embodiments or improvements that are within the scope and spirit of the present technology. Therefore, the specific structure, acts, or media are disclosed only as illustrative embodiments. The scope of the technology is defined by the following claims and any equivalents therein.

What is claimed is:

1. A computer-implemented method for determining acceptability of a substrate, comprising:
generating a model representing image data obtained from reference images of first substrates, each reference image including pixels that correspond to pixels of each of other reference images, the model defining, for each pixel, a range of acceptable image values;
receiving new image data obtained from a second substrate; and
updating the model to generate an updated model, including modifying the range of acceptable image values based on the new image data to generate a modified range.

2. The computer-implemented method of claim 1, wherein each reference image includes image data representing a full die of one of the first substrates, the first substrates being semiconductor substrates.

3. The computer-implemented method of claim 1, wherein the new image data represents a full die of the second substrate, the second substrate being a semiconductor substrate.

4. The computer-implemented method of claim 1, wherein the new image data represents less than a full die of the second substrate, the second substrate being a semiconductor substrate.

5. The computer-implemented method of claim 1,
wherein the range of acceptable image values is defined between a first threshold and a second threshold, and
wherein modifying the range of acceptable image values includes moving at least one of the first threshold and the second threshold.

6. The computer-implemented method of claim 1, further comprising:
determining whether there is a defect in a third substrate by comparing image data representing at least a portion of the third substrate and the updated model.

7. The computer-implemented method of claim 6,
wherein a defect in the third substrate is detected, the method further comprising:
classifying the defect as acceptable or unacceptable.

8. The computer-implemented method of claim 1, wherein each of the model and the updated model defines a number of images, a mean image data value across the number of images, and a standard deviation of image data values across the number of images.

9. The computer-implemented method of claim 8, wherein the standard deviation of the model defines the range of acceptable image values and the standard deviation of the updated model defines the modified range.

10. The computer-implemented method of claim 1, wherein different ones of the reference images are obtained using different imaging equipment.

11. The computer-implemented method of claim 10, wherein imaging equipment used to obtain the new image data is different, or calibrated differently from, all imaging equipment used to obtain the reference images.

12. The computer-implemented method of claim 1, wherein a state of an environmental condition present at the second substrate when the new image data was obtained is different from a state of the environmental condition present at the first substrates when every one of the reference images was obtained.

13. The computer-implemented method of claim 1, further comprising:
receiving further new image data obtained from a third substrate; and
updating the model again to generate a further updated model, including modifying the range of acceptable image values again based on the further new image data to generate a further modified range.

14. The computer-implemented method of claim 1, wherein the model includes a plurality of data distributions, each data distribution corresponding to composite pixel data from a corresponding pixel of the reference images.

15. The computer-implemented method of claim 14, wherein each data distribution includes a distribution of pixel brightness.

16. The computer-implemented method of claim 1, wherein at least some of the first substrates are known to be acceptable.

17. The computer-implemented method of claim 1, wherein the second substrate is known to be acceptable.

18. A computer-implemented method for determining acceptability of a substrate, comprising:
generating a model representing image data obtained from reference images of a full die of first semiconductor substrates, each reference image including pixels that correspond to pixels of each of other reference images, the model defining, for each pixel, a range of acceptable image values;
receiving new image data obtained from a full die image of a second semiconductor substrate;
determining that an imaging factor not relevant to substrate acceptability was different when the full die image of the second semiconductor substrate was obtained and when the reference images were obtained, and based thereon:
updating the model to generate an updated model, including modifying the range of acceptable image values based on the new image data to generate a modified range.

19. The computer-implemented method of claim 18, further comprising:
determining that a die of the second semiconductor substrate corresponding to the full die image of the second semiconductor substrate is acceptable.

20. The computer-implemented method of claim 18, wherein at least one of the reference images of the full die of one of the first semiconductor substrates includes a plurality of images of portions of the full die stitched together.

21. The computer-implemented method of claim 18, further comprising:
determining whether a third substrate is acceptable or unacceptable by comparing image data representing at least a portion of the third substrate and the updated model.

22. A computer-implemented method for determining acceptability of a substrate, comprising:
generating a model representing image data obtained from reference images of first substrates, each reference image including pixels that correspond to pixels of each of other reference images, the model defining, for each pixel, a range of acceptable image values;
receiving new image data obtained from a second substrate; and, based on the new image data:
updating the model to generate an updated model, including modifying the range of acceptable image values; and
determining whether the second substrate is acceptable or unacceptable by comparing the new image data to the model.

23. The computer-implemented method of claim 22, wherein the second substrate is incorporated in a light emitting diode (LED) device.

24. The computer-implemented method of claim 23, wherein the first substrates are incorporated in light emitting diode (LED) devices.
